(19) United States
(12) Patent Application Publication
(10) Pub. No.: US 2021/0376215 A1
(43) Pub. Date: Dec. 2, 2021

(54) THERMOELECTRIC MODULE

(71) Applicants: HYUNDAI MOTOR COMPANY, Seoul (KR); KIA MOTORS CORPORATION, Seoul (KR)

(72) Inventors: Min Jae LEE, Seoul (KR); Dong Ju KO, Hwaseong-si (KR); Seo Ha KANG, Hanam-si (KR); Jae Hyun SONG, Seoul (KR); Hyun Sub LEE, Gwangju-si (KR); Byung Wook KIM, Seongnam-si (KR)

(73) Assignees: HYUNDAI MOTOR COMPANY, SEOUL (KR); KIA MOTORS CORPORATION, SEOUL (KR)

(21) Appl. No.: 17/012,907

(22) Filed: Sep. 4, 2020

(30) Foreign Application Priority Data
May 29, 2020 (KR) 10-2020-0065142

(51) Int. Cl. H01L 35/32; H01L 35/34

(52) U.S. Cl. CPC H01L 35/32; H01L 35/34

(57) ABSTRACT

A thermoelectric module is provided. The thermoelectric module includes: a first thermoelectric material unit including a first unit thermoelectric material disposed in a first direction; and a second thermoelectric material unit electrically connected to the first thermoelectric material unit and including a second unit thermoelectric material disposed in a second direction that intersects the first direction.

### CROSS-REFERENCE TO RELATED APPLICATION

This application claims priority to and the benefit of Korean Patent Application No. 10-2020-0065142 filed on May 29, 2020, the entire contents of which are incorporated herein by reference.

### TECHNICAL FIELD

The present disclosure relates to a thermoelectric module.

### BACKGROUND

A thermoelectric element refers to an element that converts thermal energy and electrical energy. The thermoelectric element is also called a thermoelectric module, a Peltier element, a thermoelectric cooler (TEC), or the like. The thermoelectric element is widely used as a cooling or heating means using the Peltier effect in which when a current flows to both ends of a circuit at which different conductors are disposed, one end is heated, and the other end is cooled.

In general, the thermoelectric module is manufactured by connecting a plurality of thermoelectric materials (e.g., P-type thermoelectric materials and N-type thermoelectric materials) in series (series circuit) on a substrate and has an advantage of having a low thermal loss and performing quick temperature control.

However, in the thermoelectric module in the related art, the plurality of thermoelectric materials is disposed in a single particular direction (e.g., a vertical direction or a horizontal direction), such that a path (heat transfer path) through which heat is transferred in the thermoelectric material may also be defined only in the single particular direction. As a result, there is a problem in that it is difficult to improve a heat dissipation performance of the thermoelectric module to a predetermined degree or more.

In addition, in the related art, since the thermoelectric materials of the thermoelectric module are disposed only in the single particular direction, there is a problem in that a posture and a position at which the thermoelectric module is mounted are restricted. Further, there is a problem in that it is difficult to mount the thermoelectric module at a posture and a position at which efficiency in cooling a subject (e.g., a battery cell) may be maximized in accordance with properties (e.g., a structure and a shape) of the subject.

Therefore, recently, various types of research are conducted to freely mount the thermoelectric module in accordance with the properties of the subject while ensuring the heat dissipation performance of the thermoelectric module, but the research result is still insufficient. Accordingly, there is a need for development of a thermoelectric module capable of being freely mounted while ensuring a heat dissipation performance.

### SUMMARY

The present disclosure provides a thermoelectric module capable of improving a heat dissipation performance.

The present disclosure also dissipates heat by transferring the heat in two or more different directions.

The present disclosure improves a degree of freedom of disposing a thermoelectric module and improve a degree of design freedom and spatial utilization.

The present disclosure improves efficiency in cooling a subject and improve stability and reliability.

The object to be achieved by the exemplary embodiment is not limited to the above-mentioned objects, but also includes objects or effects that may be recognized from the solutions or the exemplary embodiments described below.

An exemplary embodiment of the present disclosure provides a thermoelectric module including: a first thermoelectric material unit including first unit thermoelectric materials disposed in a first direction; and a second thermoelectric material unit electrically connected to the first thermoelectric material unit and including second unit thermoelectric materials disposed in a second direction that intersects the first direction.

This is to improve a heat dissipation performance of the thermoelectric module and improve stability and reliability.

That is, in a thermoelectric module in the related art, thermoelectric materials are disposed in a single particular direction (e.g., a vertical direction or a horizontal direction), such that a path (heat transfer path) through which heat is transferred in the thermoelectric material may also be defined only in the single particular direction. As a result, there is a problem in that it is difficult to improve a heat dissipation performance of the thermoelectric module to a predetermined degree or more. Further, there is a problem in that it is difficult to mount the thermoelectric module at a posture and a position at which efficiency in cooling a subject may be maximized in accordance with properties (e.g., a structure and a shape) of the subject.

However, according to the exemplary embodiment of the present disclosure, the first unit thermoelectric material and the second unit thermoelectric material are disposed in the directions that intersect each other, such that the heat may be transferred in two or more different directions. As a result, it is possible to obtain an advantageous effect of improving the heat dissipation performance of the thermoelectric module.

Moreover, according to the exemplary embodiment of the present disclosure, the first unit thermoelectric material and the second unit thermoelectric material are disposed in the directions that intersect each other, such that a degree of design freedom and spatial utilization may be improved, and the thermoelectric module may be easily mounted without being limited by properties of the subject, such as a structure and a shape of the subject.

Furthermore, the present disclosure may improve a degree of freedom of arranging the thermoelectric module, and as a result, the thermoelectric module may be mounted at an optimum position and an optimum posture that enable a portion of the subject where a relatively large amount of heat is generated to be concentratedly cooled.

According to the exemplary embodiment of the present disclosure, a first heat transfer path may be defined along the first unit thermoelectric material of the first thermoelectric material unit, a second heat transfer path may be defined along the second unit thermoelectric material of the second thermoelectric material unit, and the first heat transfer path and the second heat transfer path may be connected in series.

The first heat transfer path may be defined to have various shapes in accordance with required conditions and design specifications. As an example, the first heat transfer path may be defined to have a straight or curved shape.

The second heat transfer path may be defined to have various shapes in accordance with required conditions and design specifications. As an example, the second heat transfer path may be defined to have a straight or curved shape.

According to the exemplary embodiment of the present disclosure, the first heat transfer path may be defined in a vertical direction, and the second heat transfer path may be defined in a horizontal direction perpendicular to the vertical direction.

According to the exemplary embodiment of the present disclosure, the first unit thermoelectric material may include at least one of a first N-type thermoelectric material and a first P-type thermoelectric material disposed in the first direction.

As an example, the first thermoelectric material unit may include: a first substrate; the first N-type thermoelectric material provided on the first substrate; the first P-type thermoelectric material spaced apart from the first N-type thermoelectric material and provided on the first substrate; first electrodes individually connected to one end of the first N-type thermoelectric material and one end of the first P-type thermoelectric material, respectively; and a second electrode configured to electrically connect the other end of the first N-type thermoelectric material and the other end of the first P-type thermoelectric material.

According to the exemplary embodiment of the present disclosure, the second unit thermoelectric material may include at least one of a second N-type thermoelectric material and a second P-type thermoelectric material disposed in the second direction.

As an example, the second thermoelectric material unit may include: a second substrate; the second N-type thermoelectric materials provided on the second substrate; the second P-type thermoelectric materials spaced apart from the second N-type thermoelectric materials and provided on the second substrate; third electrodes individually connected to one end of each of the second N-type thermoelectric materials and one end of each of the second P-type thermoelectric materials, respectively; and fourth electrodes each configured to electrically connect the other end of each of the second N-type thermoelectric materials and the other end of each of the second P-type thermoelectric materials.

According to the exemplary embodiment of the present disclosure, the thermoelectric module may include a third thermoelectric material unit electrically connected to the second thermoelectric material unit and including third unit thermoelectric materials disposed in a third direction that intersects the second direction, a third heat transfer path may be defined along the third unit thermoelectric material of the third thermoelectric material unit, and the third heat transfer path and the second heat transfer path may be connected in series.

According to the exemplary embodiment of the present disclosure, the thermoelectric module may include a heat sink connected to at least one of the first thermoelectric material unit and the second thermoelectric material unit.

In particular, any one of the first thermoelectric material unit and the second thermoelectric material unit may be connected to a subject, and heat generated from the subject may be transferred to the heat sink via the first heat transfer path and the second heat transfer path.

More particularly, the thermoelectric module according to the exemplary embodiment of the present disclosure may be connected directly to a battery cell of a battery module for a vehicle.

In the related art, a cooling fan (not illustrated) needs to be mounted on the battery module, and the battery module needs to be cooled by heat transfer (convection) created by air forcedly flowing by the cooling fan. As a result, there is a problem in that efficiency in cooling the battery module is low, and a degree of design freedom and spatial utilization deteriorate because a space in which the cooling fan is mounted needs to be separately provided.

However, according to the exemplary embodiment of the present disclosure, the thermoelectric module is connected to the battery cell, and the heat generated from the battery cell is transferred (conducted) directly to the thermoelectric module, thereby obtaining an advantageous effect of improving efficiency in cooling the battery module.

Moreover, according to the exemplary embodiment of the present disclosure, it is possible to minimize a size of the cooling fan for cooling the battery module or remove the cooling fan, thereby obtaining an advantageous effect of minimizing noise caused by the operation of the cooling fan and reducing power consumption.

Furthermore, according to the exemplary embodiment of the present disclosure, the heat generated from the battery cell is transferred through the first heat transfer path and the second heat transfer path defined in the different directions, such that the heat sink may be mounted at a posture and a position that do not block (or interfere with) an air passageway through which the heat is dissipated to the outside from the inside of the battery module. Therefore, it is possible to obtain an advantageous effect of ensuring a flow of hot air discharged to the outside through the air passageway and minimizing a deterioration in operating performance (heat dissipation performance) of the heat sink which is caused by the hot air that passes through the air passageway.

### DRAWINGS

In order that the disclosure may be well understood, there will now be described various forms thereof, given by way of example, reference being made to the accompanying drawings, in which:

FIG. 1 is a view for explaining a thermoelectric module in one form of the present disclosure.

FIG. 2 is a view for explaining a first thermoelectric material unit of the thermoelectric module in one form of the present disclosure.

FIG. 3 is a top plan view for explaining a second thermoelectric material unit of the thermoelectric module in one form of the present disclosure.

FIG. 4 is a cross-sectional view for explaining the second thermoelectric material unit of the thermoelectric module in one form of the present disclosure.

FIG. 5 is a view for explaining a first heat transfer path and a second heat transfer path in the thermoelectric module in one form of the present disclosure.

FIGS. 6 to 13 are views for explaining modified examples of the first thermoelectric material unit and the second thermoelectric material unit of the thermoelectric module in one form of the present disclosure.

FIG. 14 is a view for explaining an example in which the thermoelectric module in one form of the present disclosure is mounted.

The drawings described herein are for illustration purposes only and are not intended to limit the scope of the present disclosure in any way.

### DETAILED DESCRIPTION

Hereinafter, exemplary embodiments of the present disclosure will be described in detail with reference to the accompanying drawings.

However, the technical spirit of the present disclosure is not limited to some exemplary embodiments described herein but may be implemented in various different forms. One or more of the constituent elements in the exemplary embodiments may be selectively combined and substituted within the scope of the technical spirit of the present disclosure.

In addition, unless otherwise specifically and explicitly defined and stated, the terms (including technical and scientific terms) used in the exemplary embodiments of the present disclosure may be construed as the meaning which may be commonly understood by the person with ordinary skill in the art to which the present disclosure pertains. The meanings of the commonly used terms such as the terms defined in dictionaries may be interpreted in consideration of the contextual meanings of the related technology.

In addition, the terms used in the exemplary embodiment of the present disclosure are for explaining the exemplary embodiments, not for limiting the present disclosure.

Unless particularly stated otherwise in the context of the present specification, a singular form may also include a plural form. The explanation “at least one (or one or more) of A, B, and C” described herein may include one or more of all combinations that can be made by combining A, B, and C.

In addition, the terms such as first, second, A, B, (a), and (b) may be used to describe constituent elements of the exemplary embodiments of the present disclosure.

These terms are used only for the purpose of discriminating one constituent element from another constituent element, and the nature, the sequences, or the orders of the constituent elements are not limited by the terms.

Further, when one constituent element is described as being ‘connected’, ‘coupled’, or ‘attached’ to another constituent element, one constituent element can be connected, coupled, or attached directly to another constituent element or connected, coupled, or attached to another constituent element through still another constituent element interposed therebetween.

In addition, the explanation “one constituent element is formed or disposed above (on) or below (under) another constituent element” includes not only a case in which the two constituent elements are in direct contact with each other, but also a case in which one or more additional constituent elements are formed or disposed between the two constituent elements. In addition, the expression “up (above) or down (below)” may include a meaning of a downward direction as well as an upward direction based on one constituent element.

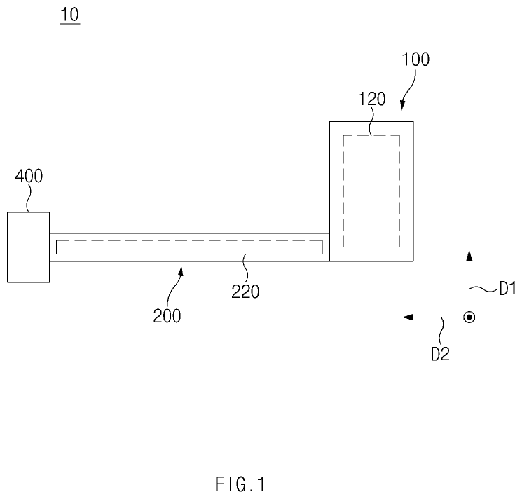

Referring to FIGS. 1 to 14, a thermoelectric module 10 according to an exemplary embodiment of the present disclosure includes: a first thermoelectric material unit 100 including first unit thermoelectric materials 120 disposed in a first direction D1, and a second thermoelectric material unit 200 electrically connected to the first thermoelectric material unit 100 and including second unit thermoelectric materials 220 disposed in a second direction D2 that intersects the first direction D1.

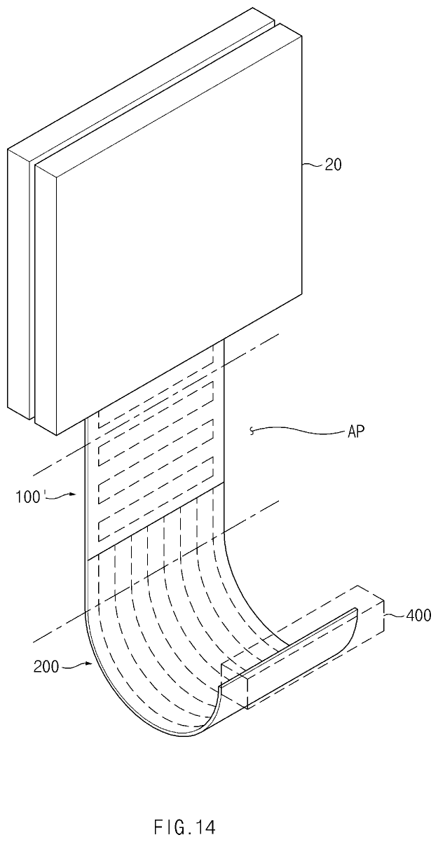

For reference, the thermoelectric module 10 according to the exemplary embodiment of the present disclosure may be mounted on various subjects (see 20 in FIG. 14) in accordance with required conditions and design specifications, and the present disclosure is not restricted or limited by the type and the structure of the subject 20.

As an example, the thermoelectric module 10 according to the exemplary embodiment of the present disclosure may be mounted on the subject 20 in order to dissipate heat generated by the subject 20 (e.g., a battery cell).

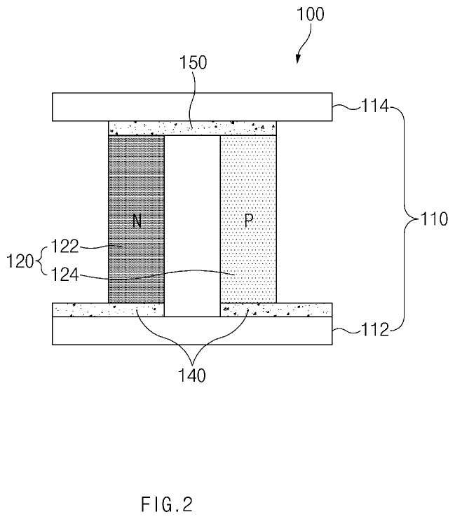

Referring to FIG. 2, the first thermoelectric material unit 100 includes the first unit thermoelectric materials 120 disposed in the first direction Dl.

For reference, in the present disclosure, a direction indicated by the first direction D1 may be variously changed in accordance with required conditions and design specifications, and the present disclosure is not restricted or limited by the direction indicated by the first direction D1.

As an example, the first direction D1 may be defined as a vertical direction (an up-down direction based on FIG. 1). According to another exemplary embodiment of the present disclosure, the first direction may be defined as a horizontal direction or other directions.

The first unit thermoelectric material 120 is an element that converts thermal energy and electrical energy and is also called a Peltier element, a thermoelectric cooler (TEC), or the like. The first unit thermoelectric material 120 is widely used as a cooling or heating means using the Peltier effect in which when a current flows through the first unit thermoelectric material 120, one end of the first unit thermoelectric material 120 is heated, and the other end of the first unit thermoelectric material 120 is cooled.

According to the exemplary embodiment of the present disclosure, the first unit thermoelectric material 120 may include at least one of a first N-type thermoelectric material 122 and a first P-type thermoelectric material 124 disposed in the first direction D1.

The number of first N-type thermoelectric materials 122, the number of first P-type thermoelectric materials 124, and shapes in which the first N-type thermoelectric material 122 and the first P-type thermoelectric material 124 are arranged may be variously changed in accordance with required conditions and design specifications. As an example, the first N-type thermoelectric material 122 and the first P-type thermoelectric material 124 may be arranged in a straight pattern. According to another exemplary embodiment of the present disclosure, the first N-type thermoelectric material and the first P-type thermoelectric material may be arranged in a curved pattern or in other patterns, and the present disclosure is not restricted or limited by the arrangement shapes and the structures of the first N-type thermoelectric material 122 and the first P-type thermoelectric material 124.

According to the exemplary embodiment of the present disclosure, the first thermoelectric material unit 100 includes a first substrate 110, the first N-type thermoelectric material 122 provided on the first substrate 110, the first P-type thermoelectric material 124 spaced apart from the first N-type thermoelectric material 122 and provided on the first substrate 110, first electrodes 140 individually connected to one end of the first N-type thermoelectric material 122 and one end of the first P-type thermoelectric material 124, respectively, and a second electrode 150 configured to electrically connect the other end of the first N-type thermoelectric material 122 and the other end of the first P-type thermoelectric material 124.

As an example, the first substrate 110 may include a first lower substrate 112 and a first upper substrate 114. The first lower substrate 112 may be provided to maintain a shape of the thermoelectric module 10 and protect the first unit thermoelectric material 120 from the external environment.

The structure and the material of the first substrate 110 may be variously changed in accordance with required conditions and design specifications, and the present disclosure is not restricted or limited by the material and the shape of the first substrate 110.

The first N-type thermoelectric material 122 is provided on an upper portion of the first lower substrate 112 (based on FIG. 2) and protrudes in the first direction Dl.

The first P-type thermoelectric material 124 is provided on the upper portion of the first lower substrate 112 (based on FIG. 2) and protrudes in the first direction D1. The first P-type thermoelectric material 124 is disposed to be spaced apart from the first N-type thermoelectric material 122.

The first electrodes 140 individually connected (electrically connected) to one end (e.g., a lower end) of the first N-type thermoelectric material 122 and one end (e.g., a lower end) of the first P-type thermoelectric material 124, respectively, and power is applied to the first electrodes 140 from a power supply unit (not illustrated).

Here, the application of power to the first electrodes 140 is defined as including the application of a forward current or a reverse current to the first electrodes 140. For example, the first unit thermoelectric materials 120 may be heated when the forward current is applied to the first electrodes 140, and on the contrary, the first unit thermoelectric materials 120 may be cooled when the reverse current is applied to the first electrodes 140.

As an example, the first electrode 140 may be provided at the lower end of the first unit thermoelectric material 120 (based on FIG. 2) and disposed between the first unit thermoelectric material 120 and the first lower substrate 112. According to another exemplary embodiment of the present disclosure, other layers (not illustrated) such as a conductive joining layer may be provided between the first unit thermoelectric material 120 and the first electrode 140.

The first electrode 140 may be made of a typical metal material capable of being electrically connected to the first unit thermoelectric material 120, and the present disclosure is not restricted or limited by the material of the first electrode 140. As an example, the first electrode 140 may be made of at least one selected from a group consisting of copper (Cu), nickel (Ni), carbon (C), titanium (Ti), tungsten (W), silver (Ag), platinum (Pt), palladium (Pd), and aluminum (Al).

The second electrode 150 may be provided to electrically connect the other end (e.g., an upper end) of the first N-type thermoelectric material 122 and the other end (e.g., an upper end) of the first P-type thermoelectric material 124, and the first upper substrate 114 may support the second electrode 150.

More specifically, the second electrode 150 is structured to be simultaneously connected to the first N-type thermoelectric material 122 and the first P-type thermoelectric material 124 that constitute the first unit thermoelectric materials 120, and the present disclosure is not restricted or limited by the structure of the second electrode 150.

The second electrode 150 may be made of a typical metal material capable of being electrically connected to the first unit thermoelectric material 120, and the present disclosure is not restricted or limited by the material of the second electrode 150. As an example, the second electrode 150 may be made of at least one selected from a group consisting of copper (Cu), nickel (Ni), carbon (C), titanium (Ti), tungsten (W), silver (Ag), platinum (Pt), palladium (Pd), and aluminum (Al).

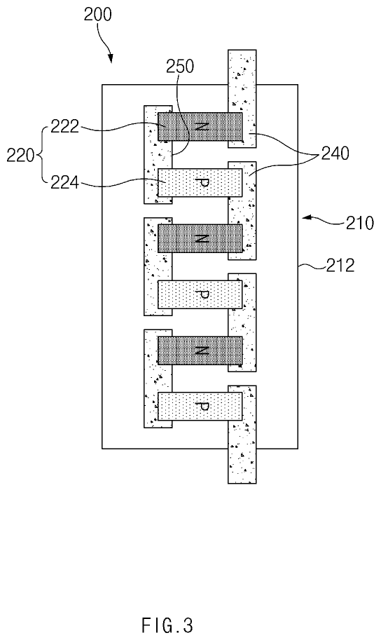

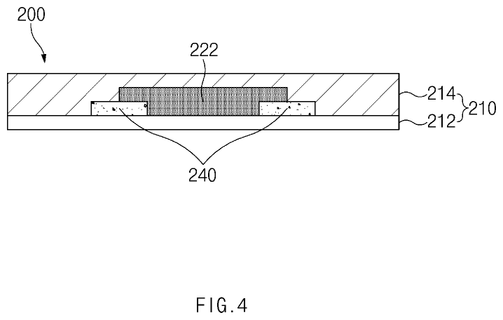

Referring to FIGS. 3 and 4, the second thermoelectric material unit 200 includes the second unit thermoelectric materials 220 disposed in the second direction D2 that intersects the first direction D1, and the second thermoelectric material unit 200 may be formed in the form of a thin film having flexibility.

For reference, in the present disclosure, a direction indicated by the second direction D2 may be variously changed in accordance with required conditions and design specifications, and the present disclosure is not restricted or limited by the direction indicated by the second direction D2.

As an example, the second direction D2 may be defined as a horizontal direction (a left-right direction based on FIG. 1). According to another exemplary embodiment of the present disclosure, the second direction may be defined as the vertical direction or other directions.

The second unit thermoelectric material 220 is an element that converts thermal energy and electrical energy and is also called a Peltier element, a thermoelectric cooler (TEC), or the like. The second unit thermoelectric material 220 is widely used as a cooling or heating means using the Peltier effect in which when a current flows through the second unit thermoelectric material 220, one end of the second unit thermoelectric material 220 is heated, and the other end of the second unit thermoelectric material 220 is cooled.

According to the exemplary embodiment of the present disclosure, the second unit thermoelectric material 220 may include at least one of a second N-type thermoelectric material 222 and a second P-type thermoelectric material 224 disposed in the second direction D2.

The number of second N-type thermoelectric materials 222, the number of second P-type thermoelectric materials 224, and shapes in which the second N-type thermoelectric material 222 and the second P-type thermoelectric material 224 are arranged may be variously changed in accordance with required conditions and design specifications. As an example, the second N-type thermoelectric material 222 and the second P-type thermoelectric material 224 may be arranged in a straight pattern. According to another exemplary embodiment of the present disclosure, the second N-type thermoelectric material and the second P-type thermoelectric material may be arranged in a curved pattern or in other patterns, and the present disclosure is not restricted or limited by the arrangement shapes and the structures of the second N-type thermoelectric material 222 and the second P-type thermoelectric material 224.

As an example, the second unit thermoelectric material 220 may be formed by performing printing (e.g., screen printing) on a second substrate 210 with an ink composition made by mixing powder for a thermoelectric semiconductor element (e.g., at least one selected from a group consisting of Bi—Te-based alloy powder, Pb—Te-based alloy powder, Si—Ge-based alloy powder, Fe—Si-based alloy powder, and Co—Sb-based alloy powder), a binder, and the like, and then sintering the ink composition by photonic sintering (e.g., sintering the ink composition by irradiating the ink composition with xenon white light) at room temperature.

According to the exemplary embodiment of the present disclosure, the second thermoelectric material unit 200 includes the second substrate 210, the second N-type thermoelectric materials 222 provided on the second substrate 210, the second P-type thermoelectric materials 224 spaced apart from the second N-type thermoelectric materials 222 and provided on the second substrate 210, third electrodes 240 individually connected to one end of each of the second N-type thermoelectric materials 222 and one end of each of the second P-type thermoelectric materials 224, respectively, and fourth electrodes 250 each configured to electrically connect the other end of each of the second N-type thermoelectric materials 222 and the other end of each of the second P-type thermoelectric materials 224.

As an example, the second substrate 210 may include a second lower substrate 212 and a second upper substrate 214. The second lower substrate 212 may be provided to maintain a shape of the thermoelectric module 10 and protect the second unit thermoelectric material 220 from the external environment.

The structure and the material of the second substrate 210 may be variously changed in accordance with required conditions and design specifications, and the present disclosure is not restricted or limited by the material and the shape of the second substrate 210.

In the related art, because the thermoelectric material is formed by sintering through a heat treatment at a high temperature (350° C. or more) and/or under a high pressure, there is a problem in that it is difficult to use a flexible substrate vulnerable to heat during the sintering.

However, according to the exemplary embodiment of the present disclosure, the second unit thermoelectric material 220 is formed by the photonic sintering at room temperature, such that the second substrate 210 is not deformed by heat, and as a result, the second substrate 210 may be made of a flexible material that may be flexibly bent.

The second substrate 210 may be made of various flexible materials in accordance with required conditions and design specifications. As an example, the second substrate 210 may be made of at least one selected from a group consisting of polyethylene terephthalate (PET), polyimide (PI), polycarbonate (PC), and polyacrylonitrile (PAN).

The second N-type thermoelectric material 222 is formed in the form of a thin and flat layer on an upper portion of the second lower substrate 212 (based on FIGS. 3 and 4), and disposed such that a longitudinal direction of the second N-type thermoelectric material 222, which has a length greater than a width, is directed in the second direction D2.

The second P-type thermoelectric material 224 is formed in the form of a thin and flat layer on the upper portion of the second lower substrate 212 (based on FIGS. 3 and 4), and disposed to be spaced apart from the second N-type thermoelectric material 222 such that a longitudinal direction of the second P-type thermoelectric material 224, which has a length greater than a width, is directed in the second direction D2.

For reference, according to the exemplary embodiment of the present disclosure, the configuration in which the second unit thermoelectric material 220 is formed in the form of a thin and flat layer unlike the first unit thermoelectric material 120 has been described as an example. However, according to another exemplary embodiment of the present disclosure, the second unit thermoelectric material may be formed to protrude in the first direction, like the first unit thermoelectric material.

The third electrodes 240 individually connected (electrically connected) to one end (e.g., a right end based on FIG. 3) of each of the second N-type thermoelectric materials 222 and one end (e.g., a right end based on FIG. 3) of each of the second P-type thermoelectric materials 224, respectively, and power is applied to the third electrodes 240 from the power supply unit (not illustrated).

In this case, the application of power to the third electrodes 240 is defined as including the application of a forward current or a reverse current to the third electrodes 240. For example, the second unit thermoelectric materials 220 may be heated when the forward current is applied to the third electrodes 240, and on the contrary, the second unit thermoelectric materials 220 may be cooled when the reverse current is applied to the third electrodes 240.

As an example, the third electrode 240 may be provided on a lower portion of the second unit thermoelectric material 220 (based on FIG. 4) and disposed between the second unit thermoelectric material 220 and the second lower substrate 212. According to another exemplary embodiment of the present disclosure, other layers (not illustrated) such as a conductive joining layer may be provided between the second unit thermoelectric material 220 and the third electrode 240.

The third electrode 240 may be made of a typical metal material capable of being electrically connected to the second unit thermoelectric material 220, and the present disclosure is not restricted or limited by the material of the first electrode 140. As an example, the third electrode 240 may be made of at least one selected from a group consisting of copper (Cu), nickel (Ni), carbon (C), titanium (Ti), tungsten (W), silver (Ag), platinum (Pt), palladium (Pd), and aluminum (Al).

The fourth electrode 250 is provided to electrically connect the other end (e.g., a left end based on FIG. 3) of each of the second N-type thermoelectric materials 222 and the other end (e.g., a left end based on FIG. 3) of each of the second P-type thermoelectric materials 224. The second upper substrate 214 may be stacked on an upper portion of the second lower substrate 212 so as to cover the second unit thermoelectric materials 220, the third electrodes 240, and the fourth electrodes 250.

More specifically, the fourth electrode 250 is structured to be simultaneously connected to the second N-type thermoelectric material 222 and the second P-type thermoelectric material 224 that constitute the second unit thermoelectric material 220, and the present disclosure is not restricted or limited by the structure of the fourth electrode 250.

The fourth electrode 250 may be made of a typical metal material capable of being electrically connected to the second unit thermoelectric material 220, and the present disclosure is not restricted or limited by the material of the fourth electrode 250. As an example, the fourth electrode 250 may be made of at least one selected from a group consisting of copper (Cu), nickel (Ni), carbon (C), titanium (Ti), tungsten (W), silver (Ag), platinum (Pt), palladium (Pd), and aluminum (Al).

Meanwhile, the second thermoelectric material unit 200 may be manufactured by various methods in accordance with required conditions.

As an example, a method of manufacturing the second thermoelectric material unit 200 may include forming a plurality of third electrodes 230 and a plurality of fourth electrodes 240 on the second substrate 210 (e.g., the second lower substrate), forming the second unit thermoelectric materials 220 by using an ink composition so that the second unit thermoelectric materials 220 are connected to the plurality of third electrodes 230 and the plurality of fourth electrodes 240, and performing photonic sintering on the second unit thermoelectric materials 220 at room temperature.

In particular, based on 100 parts by weight of powder for a thermoelectric semiconductor element, the ink composition may include a binder of 5 to 20 parts by weight, more particularly, 8 to 17 parts by weight. If the binder content is lower than 5 parts by weight based 100 parts by weight of the powder for a thermoelectric semiconductor element, the attachment property to the second substrate 210 may deteriorate. If the binder content is higher than 20 parts by weight based 100 parts by weight of the powder for a thermoelectric semiconductor element, there may be a problem in that a thermoelectric performance deteriorates.

In particular, the second unit thermoelectric material 220 may be formed by photonic sintering by irradiation with xenon white light, which has energy of 5 to 15 J/cm², for 1/1000 to 1/100 seconds with the applied voltage of 200 to 400 V. Unlike thermal sintering at a high temperature and under a high pressure in the related art, the second unit thermoelectric material 220 is formed by the photonic sintering at room temperature and under a normal pressure, such that the second unit thermoelectric material 220 has fine tissue different from that of the thermoelectric material in the related art. Specifically, an average content of carbon atoms (the binder content) is adjusted in accordance with a profile of a thickness in the second unit thermoelectric material 220, thereby improving the thermoelectric performance and increasing attachment force to the substrate.

As described above, since the second unit thermoelectric material 220 is formed by the photonic sintering, penetration power may become excellent by instantaneous optical pulses, and the sintering may be performed within a noticeably short time at room temperature. Therefore, the photonic sintering is suitable for high-speed sintering through roll-to-roll (R2R) printing because a large-area process may be implemented even at a low temperature.

More particularly, in the second unit thermoelectric material 220, an average content of carbon atoms contained at a lower end of the second unit thermoelectric material 220 (i.e., a portion to a point that corresponds to 30% of an average thickness from a bottom surface of the lower portion of the second unit thermoelectric material) may be higher than two times or more an average content of carbon atoms contained at an upper end of the second unit thermoelectric material 220 (i.e., the remaining portion to a point that corresponds to 70% of the average thickness of the second unit thermoelectric material. When the above-mentioned ranges are satisfied, the thermoelectric performance of the second unit thermoelectric material 220 may be improved, and the attachment force to the second substrate 210 may be increased.

As an example, the average thickness of the second unit thermoelectric material 220 may be 10 to 40 μm, specifically, 10 to 35 μm, and more specifically, 15 to 30 μm. If the average thickness of the second unit thermoelectric material 220 is smaller than 10 μm, there is concern that the thermoelectric performance deteriorates. If the average thickness of the second unit thermoelectric material 220 is larger than 40 μm, the second unit thermoelectric material 220 has brittleness, and the attachment force to the second substrate 210 may deteriorate.

According to the exemplary embodiment of the present disclosure, a first heat transfer path TP1 is defined along the first unit thermoelectric material 120 of the first thermoelectric material unit 100, a second heat transfer path TP2 is defined along the second unit thermoelectric material 220 of the second thermoelectric material unit 200, and the first heat transfer path TP1 and the second heat transfer path TP2 are connected in series.

In this case, the first heat transfer path TP1 is defined as a path through which heat is transferred (the current flows) in the first unit thermoelectric material 120, and the second heat transfer path TP2 is defined as a path through which heat is transferred in the second unit thermoelectric material 220.

Further, the configuration in which the first heat transfer path TP1 and the second heat transfer path TP2 are connected in series means that the heat transferred through the first heat transfer path TP1 may be continuously transferred through the second heat transfer path TP2.

The first heat transfer path TP1 may be defined in accordance with the structure and the arrangement shape of the first unit thermoelectric material 120, and the present disclosure is not restricted or limited by the shape and the structure of the first heat transfer path TP1.

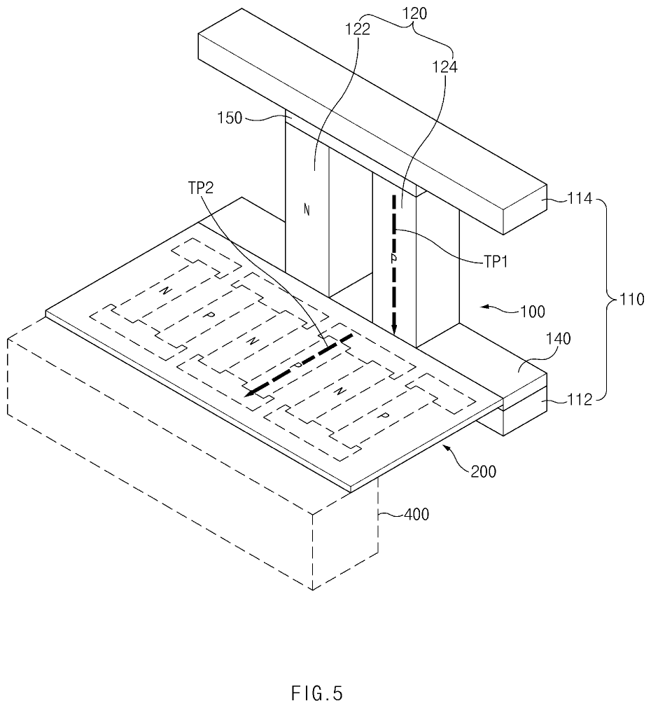

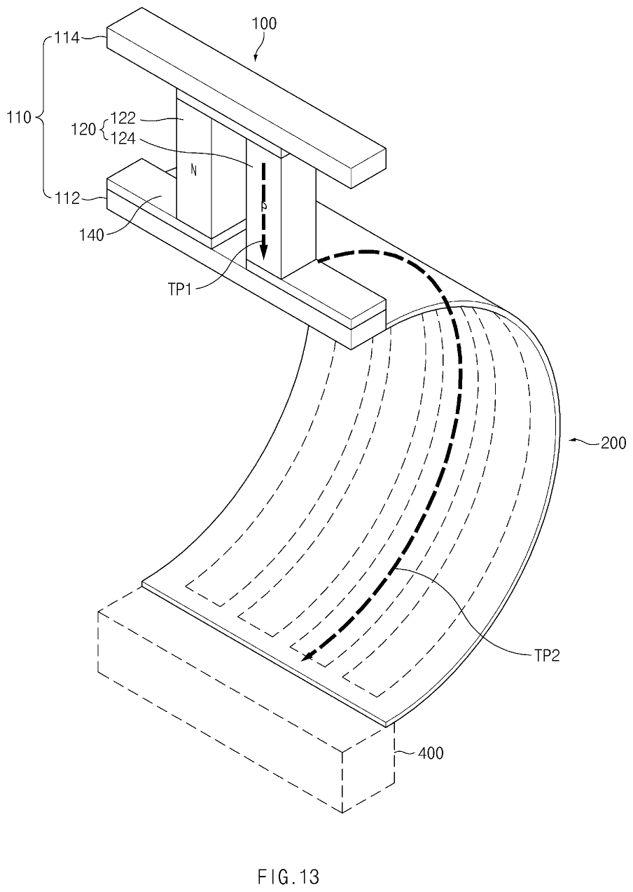

As an example, the first heat transfer path TP1 may be defined to have a straight shape (see TP1 in FIG. 5) or a curved shape (see TP2 in FIG. 13). According to another exemplary embodiment of the present disclosure, the first heat transfer path may be defined in a zigzag pattern or defined to have other structures.

Likewise, the second heat transfer path TP2 may be defined in accordance with the structure and the arrangement shape of the second unit thermoelectric material 220, and the present disclosure is not restricted or limited by the shape and the structure of the second heat transfer path TP2.

As an example, the second heat transfer path TP2 may be defined to have a straight shape (see TP2 in FIG. 5) or a curved shape (see TP2 in FIG. 13). According to another exemplary embodiment of the present disclosure, the second heat transfer path may be defined in a zigzag pattern or defined to have other structures.

The structure for connecting the first thermoelectric material unit 100 and the second thermoelectric material unit 200 may be variously changed in accordance with required conditions and design specifications, and a connection shape between the first heat transfer path TP1 and the second heat transfer path TP2 may be defined by the structure for connecting the first thermoelectric material unit 100 and the second thermoelectric material unit 200.

As an example, referring to FIG. 5, the first thermoelectric material unit 100 and the second thermoelectric material unit 200 may be connected to form an approximately “L” shape, the first heat transfer path TP1 may be defined along the first thermoelectric material unit 100 disposed in the vertical direction (e.g., the first direction), and the second heat transfer path TP2 may be defined along the second thermoelectric material unit 200 disposed in the horizontal direction (e.g., the second direction).

According to the exemplary embodiment of the present disclosure, the thermoelectric module 10 may include a heat sink 400 connected to at least one of the first thermoelectric material unit 100 and the second thermoelectric material unit 200, and the heat, which is transferred through the first heat transfer path TP1 and the second heat transfer path TP2, may be dissipated to the outside through the heat sink 400.

As an example, referring to FIG. 5, the heat sink 400 may be connected to the second thermoelectric material unit 200 (e.g., the fourth electrode 250 of the second thermoelectric material unit 200), and the heat, which is transferred from the first heat transfer path TP1 to the second heat transfer path TP2, may be dissipated to the outside through the heat sink 400.

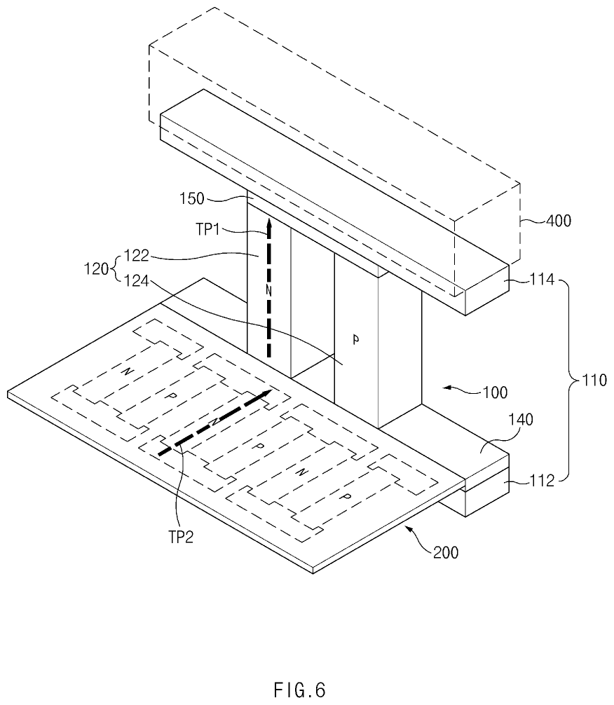

As another example, referring to FIG. 6, the heat sink 400 may be connected to the first thermoelectric material unit 100 (e.g., the first electrode 140 of the first thermoelectric material unit 100), and the heat, which is transferred from the second heat transfer path TP2 to the first heat transfer path TP1, may be dissipated to the outside through the heat sink 400.

Meanwhile, in the exemplary embodiment of the present disclosure described above and illustrated in the drawings, the configuration in which the thermoelectric module 10 includes the two thermoelectric material units (i.e., the first thermoelectric material unit and the second thermoelectric material unit) has been described as an example. However, the thermoelectric module 10 may include three or more thermoelectric material units, and the present disclosure is not restricted or limited by the number of thermoelectric material units and the structure for connecting the thermoelectric material units.

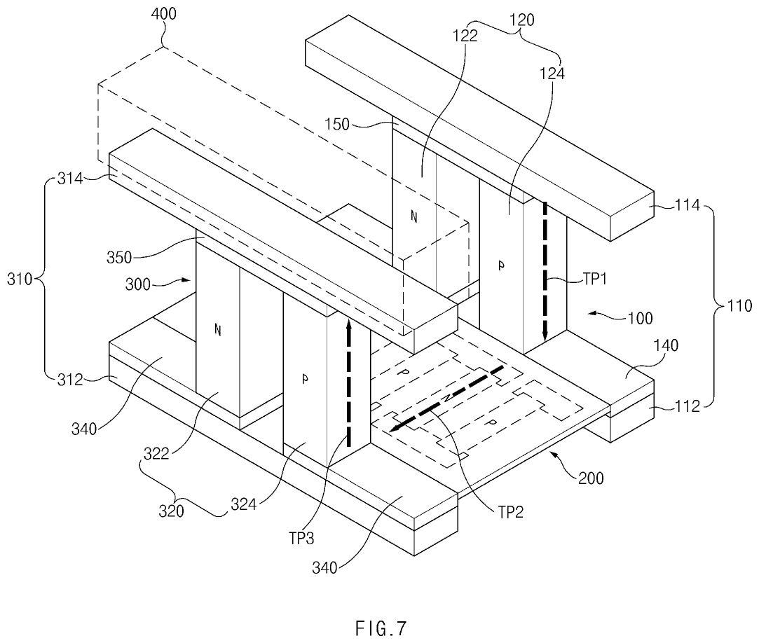

Referring to FIGS. 7 to 9, 11, and 12, the thermoelectric module 10 may include: the first thermoelectric material unit 100 including the first unit thermoelectric materials 120 disposed in the first direction D1; the second thermoelectric material unit 200 electrically connected to the first thermoelectric material unit 100 and including the second unit thermoelectric materials 220 disposed in the second direction D2 that intersects the first direction D1; and a third thermoelectric material unit 300 electrically connected to the second thermoelectric material unit 200 and including third unit thermoelectric materials 320 disposed in a third direction that intersects the second direction D2.

In particular, a third heat transfer path TP3 is defined along the third unit thermoelectric material 320 of the third thermoelectric material unit 300, and the third heat transfer path TP3 and the second heat transfer path TP2 are connected in series.

For reference, the third heat transfer path TP3 may be defined in a direction (e.g., the up-down direction) equal to or different from the direction of the first heat transfer path TP1.

The third thermoelectric material unit 300 may have a structure identical or similar to the structure of the first thermoelectric material unit 100 or the second thermoelectric material unit, and the present disclosure is not restricted or limited by the structure of the third thermoelectric material unit 300 and the structure for connecting the third thermoelectric material unit 300.

As an example, referring to FIG. 7, the third thermoelectric material unit 300 may include a third substrate 310, a third N-type thermoelectric material 322 provided on the third substrate 310, a third P-type thermoelectric material 324 spaced apart from the third N-type thermoelectric material 322 and provided on the third substrate 310, fifth electrodes 340 individually connected to one end of the third N-type thermoelectric material 322 and one end of the third P-type thermoelectric material 324, respectively, and a sixth electrode 350 configured to electrically connect the other end of the first N-type thermoelectric material 122 and the other end of the first P-type thermoelectric material 124.

As an example, the third substrate 310 may include a third lower substrate 312 and a third upper substrate 314.

In addition, the first thermoelectric material unit 100, the second thermoelectric material unit 200, and the third thermoelectric material unit 300 may be connected to form an approximately “U” shape in cooperation with one another, and the heat sink 400 may be connected to the third thermoelectric material unit 300, such that the heat, which is transferred in the order of the first heat transfer path TP1, the second heat transfer path TP2, and the third heat transfer path TP3, may be dissipated to the outside through the heat sink 400.

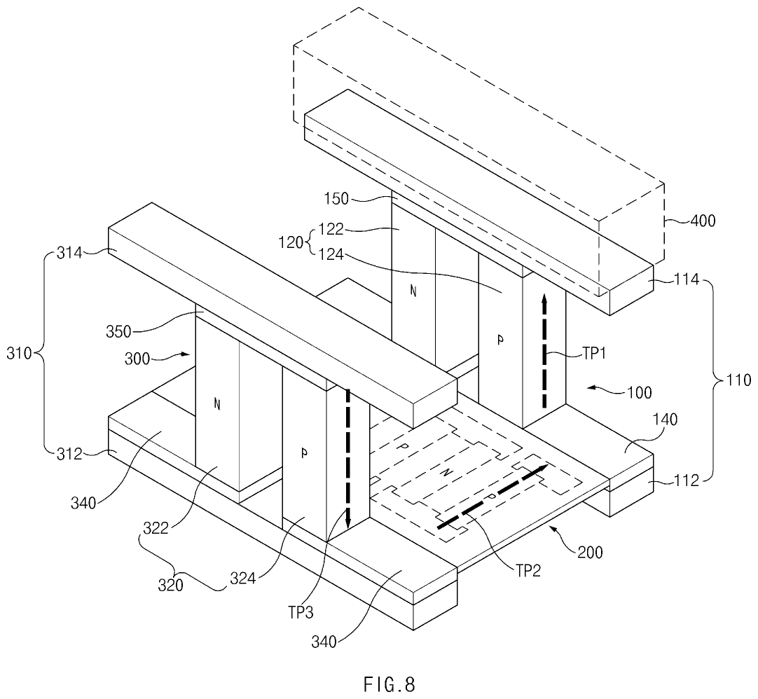

As another example, referring to FIG. 8, the first thermoelectric material unit 100, the second thermoelectric material unit 200, and the third thermoelectric material unit 300 may be connected to form an approximately “U” shape in cooperation with one another, and the heat sink 400 may be connected to the first thermoelectric material unit 100, such that the heat, which is transferred in the order of the third heat transfer path TP3, the second heat transfer path TP2, and the first heat transfer path TP1, may be dissipated to the outside through the heat sink 400.

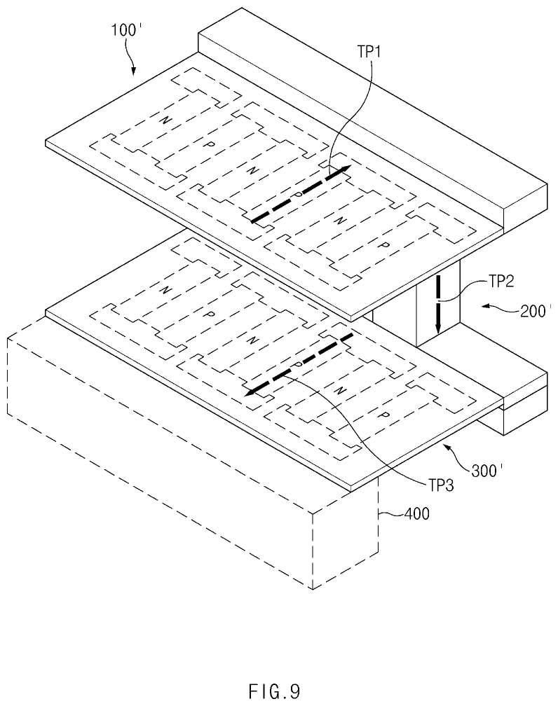

As another example, referring to FIG. 9, a first thermoelectric material unit 100′, a second thermoelectric material unit 200′, and a third thermoelectric material unit 300′ are connected to form an approximately “U” shape in cooperation with one another, each of the first thermoelectric material unit 100′ and the third thermoelectric material unit 300′ is formed in the form of a thin film having flexibility, and the second thermoelectric material unit 200′ may be formed in the form of a block (i.e., a structure having no flexibility) having a predetermined height in the first direction D1 (e.g., the up-down direction). The heat, which is transferred in the order of the first heat transfer path TP1, the second heat transfer path TP2, and the third heat transfer path TP3, may be dissipated to the outside through the heat sink 400 connected to the third thermoelectric material unit 300′.

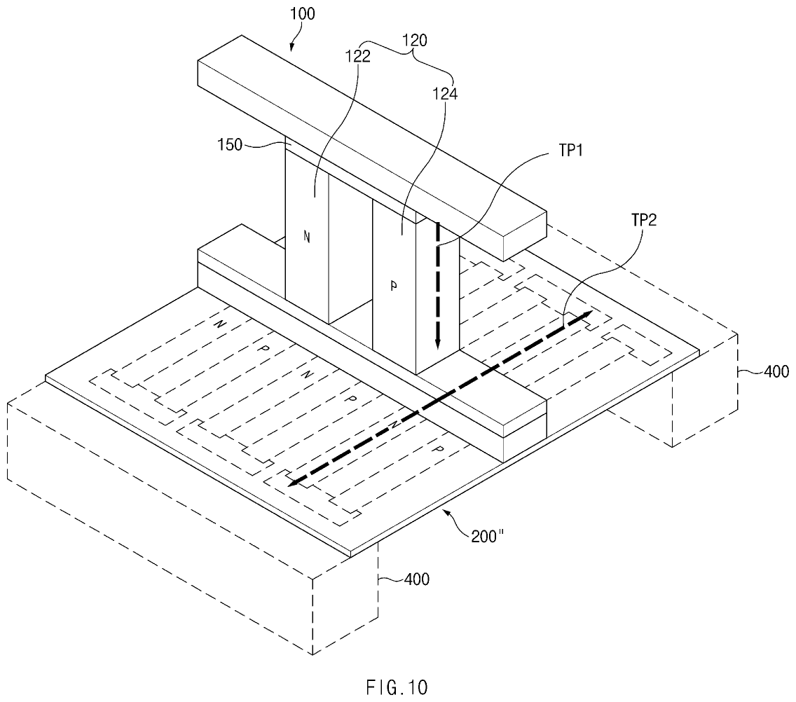

As another example, referring to FIG. 10, the thermoelectric module 10 may include the first thermoelectric material unit 100 and a second thermoelectric material unit 200″, and the first thermoelectric material unit 100 and the second thermoelectric material unit 200″ may be connected to form an approximately “T” shape in cooperation with one another.

As an example, the second thermoelectric material unit 200″ may be connected to an approximately central portion of the first thermoelectric material unit 100.

In addition, the heat sinks 400 may be connected to one end and the other end of the second thermoelectric material unit 200″, respectively, and the heat, which is transferred from the first thermoelectric material unit 100 (the first heat transfer path) to the second thermoelectric material unit 200″ (the second heat transfer path), may be divided along the second heat transfer path TP2 and dissipated to the outside through the heat sinks 400 connected to one end and the other end of the second thermoelectric material unit 200″.

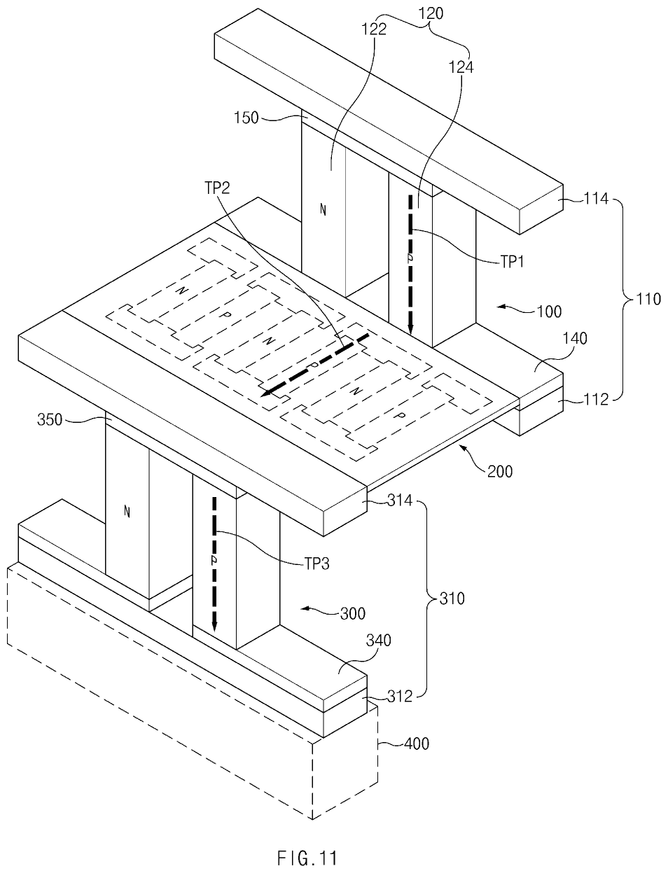

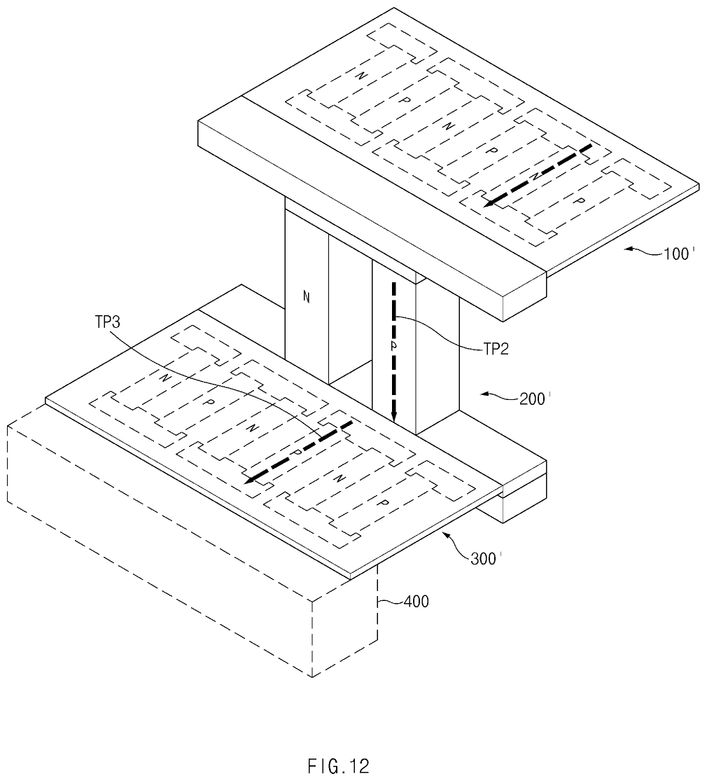

As another example, referring to FIGS. 11 and 12, the thermoelectric module 10 includes the first thermoelectric material unit 100 or 100′, the second thermoelectric material unit 200 or 200′, and the third thermoelectric material unit 300 or 300′, and the first thermoelectric material unit 100 or 100′, the second thermoelectric material unit 200 or 200′, and the third thermoelectric material unit 300 or 300′ may be continuously connected to form an approximately stepped structure in cooperation with one another. The heat, which is transferred in the order of the first heat transfer path TP1, the second heat transfer path TP2, and the third heat transfer path TP3, may be dissipated to the outside through the heat sink 400 connected to the third thermoelectric material unit 300 or 300′.

Referring to FIG. 11, each of the first thermoelectric material unit 100 and the third thermoelectric material unit 300 may be formed in the form of a block (i.e., a structure having no flexibility) having a predetermined height in the first direction D1 (e.g., the up-down direction), and the second thermoelectric material unit 200 may be formed in the form of a thin film having flexibility.

Alternatively, as illustrated in FIG. 12, each of the first thermoelectric material unit 100′ and the third thermoelectric material unit 300′ may be formed in the form of a thin film having flexibility, and the second thermoelectric material unit 200′ may be formed in the form of a block having a predetermined height in the first direction D1 (e.g., the up-down direction).

In addition, referring to FIG. 12, the thermoelectric module 10 may include the first thermoelectric material unit 100 and the second thermoelectric material unit 200, the first thermoelectric material unit 100 may be formed in the form of a block, and the second thermoelectric material unit 200 may be formed in the form of a bent (curved) film (e.g., a film having a “C” shape).

Since the second thermoelectric material unit 200 is formed in a curved shape, the second heat transfer path TP2 defined along the second unit thermoelectric material 220 may be formed in a curved shape. The heat, which is transferred from the first heat transfer path TP1 (a straight path) to the second heat transfer path TP2 (a curved path), may be dissipated to the outside through the heat sink 400.

Meanwhile, the thermoelectric module 10 according to the exemplary embodiment of the present disclosure may be mounted on various subjects 20 in accordance with required conditions and design specifications and used to dissipate the heat generated from the subject 20 to the outside.

As an example, referring to FIG. 14, any one of the first thermoelectric material unit 100′ and the second thermoelectric material unit 200 (or the third thermoelectric material unit) may be connected to the subject 20, and the heat generated from the subject 20 may be transferred to the heat sink 400 via the first heat transfer path TP1 and the second heat transfer path TP2 and then dissipated.

Hereinafter, an example in which the thermoelectric module 10 according to the exemplary embodiment of the present disclosure is connected directly to a battery cell of a battery module for a vehicle will be described as an example.

As an example, both the first thermoelectric material unit 100′ and the second thermoelectric material unit 200 each may be formed in the form of a thin film having flexibility, the first thermoelectric material unit 100′ may be connected to the subject 20 (the battery cell), and the heat sink 400 may be connected to the second thermoelectric material unit 200 disposed to be bent below the subject 20. Therefore, the heat generated from the subject 20 may be transferred to the heat sink 400 via the first heat transfer path TP1 and the second heat transfer path TP2 and then dissipated to the outside.

In the related art, a cooling fan (not illustrated) needs to be mounted on the battery module, and the battery module needs to be cooled by heat transfer (convection) created by air forcedly flowing by the cooling fan. As a result, there is a problem in that efficiency in cooling the battery module is low, and a degree of design freedom and spatial utilization deteriorate because a space in which the cooling fan is mounted needs to be separately provided.

However, according to the exemplary embodiment of the present disclosure, the thermoelectric module 10 is connected to the battery cell, and the heat generated from the battery cell is transferred (conducted) directly to the thermoelectric module 10, thereby obtaining an advantageous effect of improving efficiency in cooling the battery module.

Moreover, according to the exemplary embodiment of the present disclosure, it is possible to minimize a size of the cooling fan for cooling the battery module or remove the cooling fan, thereby obtaining an advantageous effect of minimizing noise caused by the operation of the cooling fan and reducing power consumption.

Furthermore, according to the exemplary embodiment of the present disclosure, the heat generated from the battery cell is transferred through the first heat transfer path and the second heat transfer path defined in the first thermoelectric material unit 100′ and the second thermoelectric material unit 200, such that the heat sink 400 may be mounted at a posture and a position that do not block (or interfere with) an air passageway AP through which the heat is dissipated to the outside from the inside of the battery module. Therefore, it is possible to obtain an advantageous effect of ensuring a flow of hot air discharged to the outside through the air passageway AP and minimizing a deterioration in operating performance (heat dissipation performance) of the heat sink 400 which is caused by the hot air that passes through the air passageway AP.

While the exemplary embodiments have been described above, but the exemplary embodiments are just illustrative and not intended to limit the present disclosure. It can be appreciated by those skilled in the art that various modifications and alterations, which are not described above, may be made to the present exemplary embodiment without departing from the intrinsic features of the present exemplary embodiment. For example, the respective constituent elements specifically described in the exemplary embodiments may be modified and then carried out. Further, it should be interpreted that the differences related to the modifications and alterations are included in the scope of the present disclosure defined by the appended claims.

As described above, according to the exemplary embodiment of the present disclosure, it is possible to obtain an advantageous effect of improving the heat dissipation performance.

In particular, according to the exemplary embodiment of the present disclosure, the heat is transferred in the two or more different directions and then dissipated, and as a result, it is possible to obtain an advantageous effect of ensuring the heat dissipation performance and minimizing a deterioration in performance of the thermoelectric module.

In addition, according to the exemplary embodiment of the present disclosure, it is possible to obtain an advantageous effect of improving a degree of freedom of arranging the thermoelectric module and improving a degree of design freedom and spatial utilization.

In addition, according to the exemplary embodiment of the present disclosure, it is possible to obtain an advantageous effect of improving efficiency in cooling a subject and improving stability and reliability.

The description of the disclosure is merely exemplary in nature and, thus, variations that do not depart from the substance of the disclosure are intended to be within the scope of the disclosure. Such variations are not to be regarded as a departure from the spirit and scope of the disclosure.

1. A thermoelectric module comprising:
a first thermoelectric material unit comprising a first unit thermoelectric material disposed in a first direction; and
a second thermoelectric material unit electrically connected to an end of the first thermoelectric material unit and comprising a second unit thermoelectric material disposed in a second direction that intersects the first direction not to overlap the first thermoelectric material,
wherein:
a first heat transfer path is defined along the first unit thermoelectric material of the first thermoelectric material unit,
a second heat transfer path is defined along the second unit thermoelectric material of the second thermoelectric material unit, and
the first heat transfer path and the second heat transfer path are connected in series.

2. (canceled)

3. The thermoelectric module of claim 1, wherein the first heat transfer path is configured to have a straight or curved shape.

4. The thermoelectric module of claim 1, wherein the second heat transfer path is configured to have a straight or curved shape.

5. The thermoelectric module of claim 1, wherein the first heat transfer path is defined in a vertical direction, and the second heat transfer path is defined in a horizontal direction perpendicular to the vertical direction.

6. The thermoelectric module of claim 1, wherein the first unit thermoelectric material comprises at least one of a first N-type thermoelectric material or a first P-type thermoelectric material disposed in the first direction.

7. The thermoelectric module of claim 6, wherein the first thermoelectric material unit comprises:
a first substrate;
the first N-type thermoelectric material provided on the first substrate;
the first P-type thermoelectric material spaced apart from the first N-type thermoelectric material and provided on the first substrate;
a first electrode individually connected to a first end of the first N-type thermoelectric material and a first end of the first P-type thermoelectric material, respectively; and
a second electrode configured to electrically connect a second end of the first N-type thermoelectric material and a second end of the first P-type thermoelectric material.

8. The thermoelectric module of claim 1, wherein the second unit thermoelectric material comprises at least one of a second N-type thermoelectric material or a second P-type thermoelectric material disposed in the second direction.

9. The thermoelectric module of claim 8, wherein the second thermoelectric material unit comprises:
a second substrate;
the second N-type thermoelectric material provided on the second substrate;
the second P-type thermoelectric material spaced apart from the second N-type thermoelectric material and provided on the second substrate;
a third electrode individually connected to a first end of the second N-type thermoelectric material and a first end of each of the second P-type thermoelectric material, respectively; and
a fourth electrode configured to electrically connect a second end of the second N-type thermoelectric material and a second end of the second P-type thermoelectric material.

10. The thermoelectric module of claim 1, wherein the module comprises:
a third thermoelectric material unit electrically connected to the second thermoelectric material unit and comprising a third unit thermoelectric material disposed in a third direction that intersects the second direction,
wherein a third heat transfer path is defined along the third unit thermoelectric material of the third thermoelectric material unit, and the third heat transfer path and the second heat transfer path are connected in series.

11. The thermoelectric module of claim 1, wherein the module comprises:
a heat sink connected to at least one of the first thermoelectric material unit or the second thermoelectric material unit.

12. The thermoelectric module of claim 11, wherein any one of the first thermoelectric material unit or the second thermoelectric material unit is connected to a subject, and heat generated from the subject is transferred to the heat sink via the first heat transfer path and the second heat transfer path.
